(19) United States
(12) Patent Application Publication
(10) Pub. No.: US 2008/0067665 A1
(43) Pub. Date: Mar. 20, 2008

(54) Via structure

(76) Inventors: Azniza Binti Abd Aziz, Ipoh Perak (MY); Chan Kim Lee, (US); Kuen Yew Lam, Penang (MY)

Correspondence Address: TROP PRUNER & HU, PC, 1616 S. VOSS ROAD, SUITE 750, HOUSTON, TX, 77057-2631, US

(21) Appl. No.: 11/524,108

(22) Filed: Sep. 20, 2006

(51) Int. Cl. H01L 23/04

(52) U.S. Cl. 257/698

(57) ABSTRACT

In one embodiment, the invention may include a semiconductor package substrate with a plated-through hole (PTH) via. One or more conduits for transmitting signals can be located in the PTH via. The PTH via may shield the signals in the conduits from environmental noise (e.g., EMI). Other embodiments are described and claimed.

### BACKGROUND

Integrated circuits (IC's) are typically assembled into packages that are physically and electrically coupled to a substrate. The substrate may be a printed circuit board (PCB). However, the substrate may instead connect the IC to a PCB (e.g., motherboard). A substrate may include a number of insulation and metal layers selectively patterned to provide metal lines (referred to herein as “traces”). Regarding a PCB, the routing traces may transmit signals between electronic components and/or to input/output (I/O) pads. A large number of I/O pads require a relatively large number of routing traces. Some PCB's require multiple layers of routing traces to accommodate all of the interconnections between electronic components and I/O pads.

Routing traces located within different layers of a substrate are typically connected electrically by vias formed in the substrate. A via can be made by making a hole through some or all layers of a substrate. In some instances, the interior hole surface of the via may be coated or plated with an electrically conductive material, such as copper or tungsten. The vias can serve different roles such as transmitting power (e.g., supply voltage) or signals (e.g., I/O signals) or connecting to ground.

IC's and PCB's are becoming increasingly congested as circuit designers locate more and more components and traces on smaller and smaller substrates. This congestion is due in part to the large number of vias that are interspersed throughout the substrate. As congestion on the substrate increases, problems can occur. For example, the signals transmitted through and within a substrate can become distorted due to environmental noise. This loss of signal integrity is due, in part, to the density of components, traces and vias on the substrate. In other words, traces between vias and components must often take circuitous and lengthy routes to avoid other components. As the length of the traces increase, so too may the resistive, inductive, and capacitive properties of the traces. As these properties increase in magnitude, unwanted electromagnetic interference (EMI), increased loop inductance and cross-talk-interference may increase as well—all of which has a detrimental effect on signal integrity. The noise-related problems only increase when devices are operated at higher frequencies which are common in many devices today.

### BRIEF DESCRIPTION OF THE DRAWINGS

FIG. 1 is a cross-sectional view of a semiconductor package in accordance with one embodiment of the present invention.

FIG. 2 is a top view of a semiconductor package in accordance with another embodiment of the present invention.

FIG. 3 is a cross-sectional view of a semiconductor package in accordance with yet another embodiment of the present invention.

FIG. 4 is a cross-sectional view of a system in accordance with an embodiment of the present invention.

FIG. 5 is a top view of a semiconductor package in accordance with another embodiment of the present invention.

FIG. 6 is a flow diagram of a method of forming a semiconductor package in accordance with another embodiment of the invention.

FIG. 7 is a flow diagram of a method of forming a PCB in accordance with another embodiment of the invention.

### DETAILED DESCRIPTION

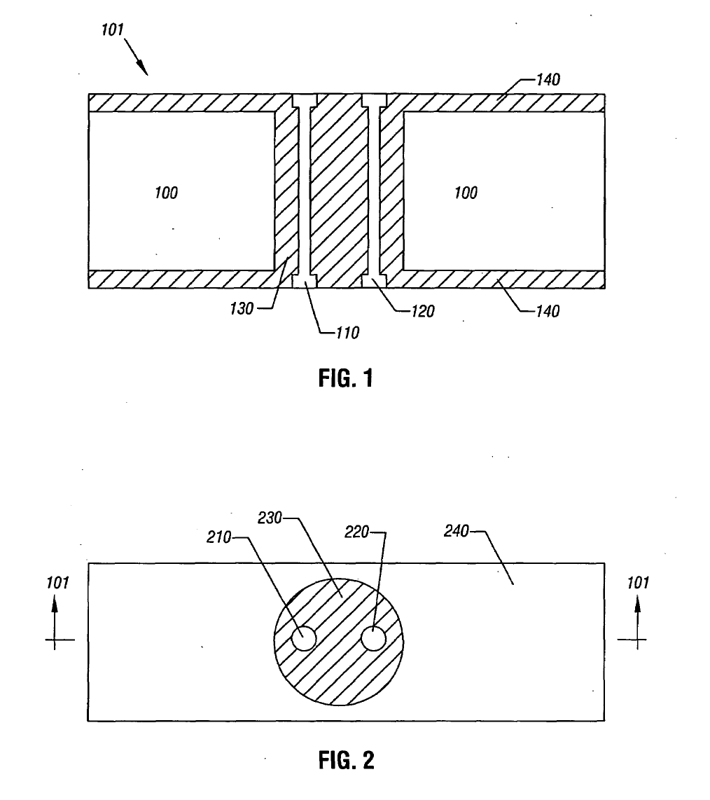

FIG. 1 shows a semiconductor package substrate 101 in accordance with one embodiment of the invention. A first opening 130 may be formed in the substrate 101 and inner layer 100 thereto. The first opening 130 may constitute a via which, in one embodiment of the invention, is a plated-through hole (PTH). However, in other embodiments of the invention, via 130 is not a PTH. Via 130 may be coupled to one or more ground planes 140 (e.g., Vss) in the substrate. A first conduit 110 and a second conduit 120 may be located within via 130. In one embodiment of the invention, conduits 110, 120 can be hollow vias. However, in other embodiments of the invention, the conduits 110, 120 may be solid. Conduits 110, 120 may conduct signals through the substrate 101. The signals transmitted in vias 110, 120 may collectively form a differential pair signal. In various embodiments of the invention, via 130 can shield the differential signal pair signal from the surrounding noise environment. In other words, via 130 may protect signal integrity by shielding signals in vias 110, 120 from surrounding EMI and signal cross-talk. In one embodiment of the invention, via 130 is connected or coupled to planes 140, which are coupled to Vss. Via 130 may serve as a return path for one or both of signals transmitted on vias 110, 120. In doing so, the return path for the signals on 110, 120 may be reduced, along with inductance, thereby increasing signal integrity. While FIG. 1 shows two conduits 110, 120 located in via 130, alternative embodiments of the invention may include fewer conduits (e.g., one) or more conduits (e.g., three) located in a single via (e.g., via 130).

FIG. 2 shows a top view of a semiconductor package in accordance with one embodiment of the present invention. The package substrate 240 may have an opening 230 that constitutes a PTH via for conducting power (e.g., supply voltage). In other embodiments, the opening 230 may be connected to ground. Vias 210, 220 can be located within via 230. As shown in FIG. 2, locating signal vias 210, 220 in via 230 can save considerable space on the substrate 240. For example, vias 210, 220, 230 may each require unique, non-overlapping space in the substrate 240 if vias 210, 220 are not located in via 230. Consequently, space on the substrate is available for other vias, thereby providing, shorter, more direct return path traces that lead to lower loop inductances and lower noise.

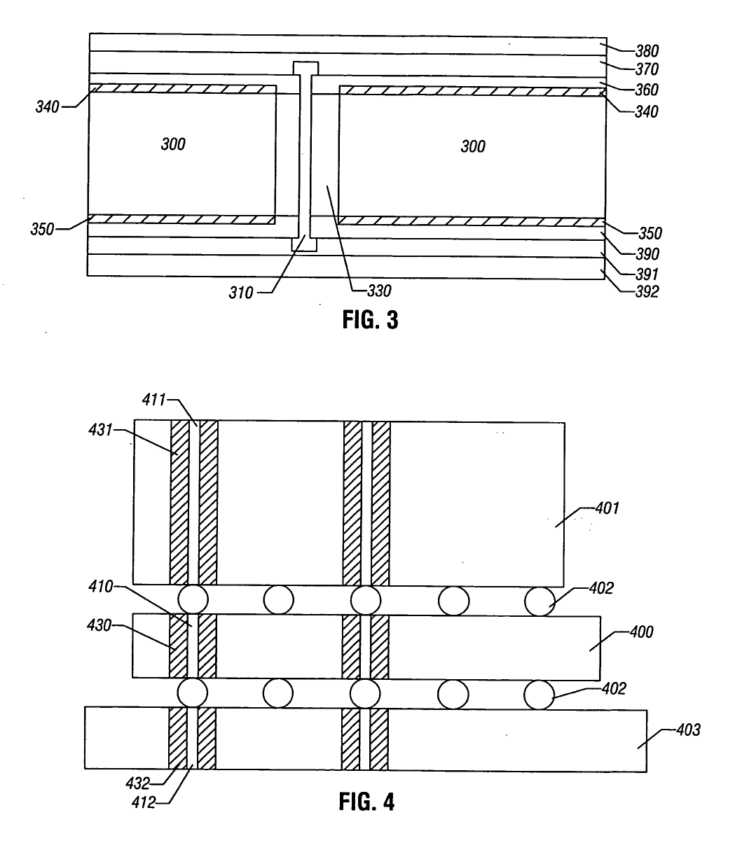

FIG. 3 is a cross-sectional view of a semiconductor package in accordance with yet another embodiment of the present invention. Package substrate 300 can have a first opening 330. Conduit 310 can be located within the first opening 330. In one embodiment of the invention, opening 330 is a PTH via and conduit 310 is an I/O signal via. Via 310 can be a buried via wherein via 310 is located between layers 380 and 391. Via 310 may transcend layers 360, 340, 300, 350, and 390. In one embodiment of the invention, layers 340, 350 are coupled to a voltage source (e.g., supply voltage) and to PTH via 330. In other embodiments of the invention, layers 340, 350 are coupled to a ground source (e.g., Vss) and to PTH via 330. Layers 360, 370, 380, 390, 391, 392 may constitute additional layers in the semiconductor package substrate. In one embodiment of the invention, via 310 connects or couples I/O traces coupled to layers 370, 391. FIG. 3 illustrates an embodiment of the invention wherein via 330 shields a signal in conduit 310 as the signal is conducted across different layers of the apparatus. This can help reduce noise coupling from multiple substrate layers. For example, coupling via 330 to one or more ground or Vss planes 340, 350 may help reduce noise as follows. Via 330 may function as a return loop for the I/O signal on via 310. These reduces the return loop path, reduces inductance and consequently increases signal integrity. While FIG. 3 shows via 330 as a buried via, via 330 may constitute other via forms (e.g., blind, through-hole) in alternative embodiments of the invention.

In an alternative embodiment of the invention, via 310 can be coupled to one or more power planes (e.g., 370, 391). Via 330 may be connected to planes 340, 350, which are coupled to, for example, Vss. Consequently, via 330 may shield power in via 310.

FIG. 4 shows a cross-sectional view of a system in accordance with another embodiment of the present invention. As shown in FIG. 4, semiconductor package substrate 400 can connect semiconductor device die 401 to motherboard 403. Substrate 400 connects die 401 to motherboard 403 using, for example, controlled collapse chip connect (C4) bumps 402. Bumps 402 may connect to one another utilizing a via 410. In one embodiment of the invention, signal vias 410, 411, 412 may communicate one or more signals through the motherboard, 403, package substrate, 400, and semiconductor device die 401. The signal vias 410, 411, 412 may be located in vias 430, 431, 432, which may be coupled to, for example, ground. The vias 430, 431, 432 may shield the signal or signals transmitted by the signal vias 410, 411, 412. In an alternative embodiment of the invention, the signal vias 410, 411, 412 may flare outwards at a junction point with the balls 402, thereby increasing the level of contact between the balls and signal vias 410, 411, 412 and decreasing or eliminating any level of contact between the balls and vias 430, 431, 432.

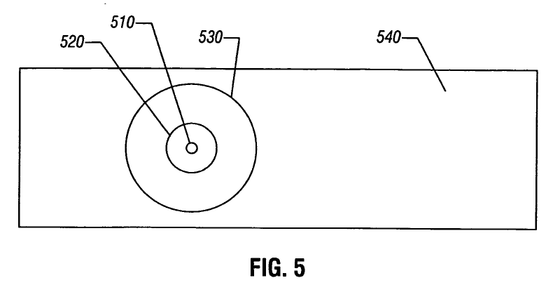

FIG. 5 is a top view of a semiconductor package in accordance with another embodiment of the present invention. In FIG. 5, semiconductor package substrate 540 has a first opening 530. Opening 530 may constitute, for example, a PTH via coupled to ground. However, in alternative embodiments of the invention, opening 530 may constitute a non plated-though hole. Conduit 520 can be located within PTH via 530. Conduit 510 can be located within conduit 520. In one embodiment of the invention, conduits 510, 520 constitute vias for conducting signals through the substrate 540. In other embodiments, one or more conduits may conduct a signal such as power. Via 530 may provide shielding for signals transmitted in vias 510, 520. In other embodiments of the invention, conduit 510 constitutes a via for conducting a signal through the substrate 540. Vias 520, 530 may provide shielding for signals transmitted in via 510.

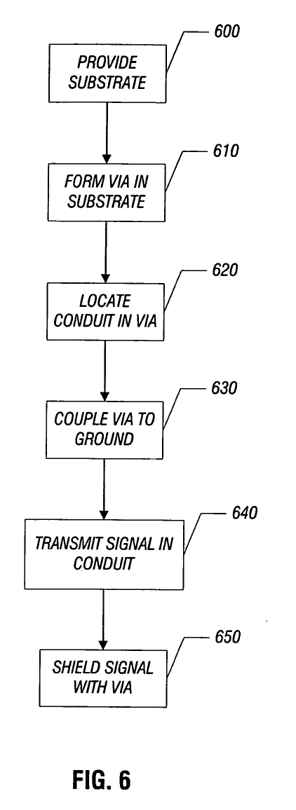

FIG. 6 is a flow diagram of a method of forming a semiconductor package in accordance with another embodiment of the invention. In block 600 of FIG. 6, a substrate is provided wherein the substrate may include, for example, a silicon (Si) substrate, an oxide layer (e.g., SiO2), a metal layer, a ferroelectric polymer layer, and an interlevel dielectric (ILD) layer (e.g., silicon oxy-fluoride). The metal layer may be composed of, for example, a single layer or a stack of metals. The metal may be aluminum in one embodiment of the invention. However, other metals such as titanium (Ti), copper (Cu), gold (Au), silver (Ag), nickel (Ni), cobalt (Co), platinum (Pt), palladium (Pd) and their alloys may be used as the metal layer. The metal layer may have a thickness of, for example, 20 to 100 nanometers.

In block 610, a via is formed by first placing a layer of photoresist on top of the substrate. A lithographic pattern may be used to define the size and location of the via or vias in the substrate. In one embodiment of the invention, the vias may be approximately 150 and 250 microns in diameter. This allows adequate conductivity between the metal layers. The vias may be etched into, for example, one or more layers in the substrate using standard etching techniques, such as plasma etching. For example, the vias may be etched through the ILD and ferroelectric polymer layers, terminating at the metal layer. Once the vias have been etched, the photoresist layer is removed from the substrate. The photoresist layer may be removed using standard plasma ash/etch process or any other suitable process for removing photoresist films.

Still referring to block 610, a metal can be deposited onto the inner walls of the via through an electroless plating process to form, for example, a PTH via. In one embodiment of the invention, the metal is nickel (Ni) and is deposited in the via using techniques known to those of ordinary skill in the art (e.g., low temperature evaporation deposition, sputtering, electroplating, electroless plating). Those of ordinary skill in the art will appreciate that other suitable metals include, for example, cobalt (Co), chromium (Cr), iron (Fe), tin (Sn), copper (Cu), silver (Ag), gold (Au), palladium (Pd), platinum (Pt), ruthenium (Ru), rhodium (Rh), iridium (Ir), and osmium (Os), their alloys and metal alloys with metalloids such as phosphorus (P), boron (B), nitrogen (N), and silicon (Si). In one embodiment of the invention, a second metal layer may then be patterned and deposited on a substrate layer (e.g., ILD layer) after the via has been created (not shown in FIG. 6). The metal layer may be deposited using techniques known to those of ordinary skill in the art (e.g., low temperature evaporation deposition, sputtering, electroplating, electroless plating).

In block 620, a photoresist layer may then be deposited on the top of the substrate (not shown in FIG. 6). A lithographic mask may expose the inner core of the via, thereby preparing a location for, as an example only, a signal via or conduit, as previously described in regards to FIGS. 1-5. In one embodiment of the invention, a dielectric material (e.g., SiO2) can be deposited within the PTH via. Multiple conduits may then be etched into the dielectric material using standard techniques such as plasma etching. A fill metal, such as copper (Cu), may then be deposited into the conduits to create signal vias. In one embodiment of the invention, the width of the signal vias is between 50-70 microns in diameter. In alternative embodiments of the invention, the signal vias may be hollow after being exposed to standard etching techniques. Those of ordinary skill in the art will appreciate that other suitable metals for the fill metal, for example, cobalt (Co), chromium (Cr), iron (Fe), tin (Sn), copper (Cu), silver (Ag), gold (Au), palladium (Pd), platinum (Pt), ruthenium (Ru), rhodium (Rh), iridium (Ir), and osmium (Os), their alloys and metal alloys with metalloids such as phosphorus (P), boron (B), nitrogen (N), and silicon (Si).

In block 630, the metal layers, as described in block 610, may be connected to, for example, ground. In alternative embodiments of the invention, the metal planes may be coupled to, for example, power planes. Signal vias may also be connected to, I/O signal sources or, in alternative embodiments of the invention, power planes. In other words, signal vias may transmit various types of signals such as, for example, power and/or an I/O signal. A power signal may be coupled to, for example, a power plane that is coupled to a supply voltage.

In block 640, I/O signals may be transmitted via the signal vias. As indicated in block 650, the shield via (connected to ground) can shield signals transmitted through the signal vias from, for example, EMI and cross-talk noise.

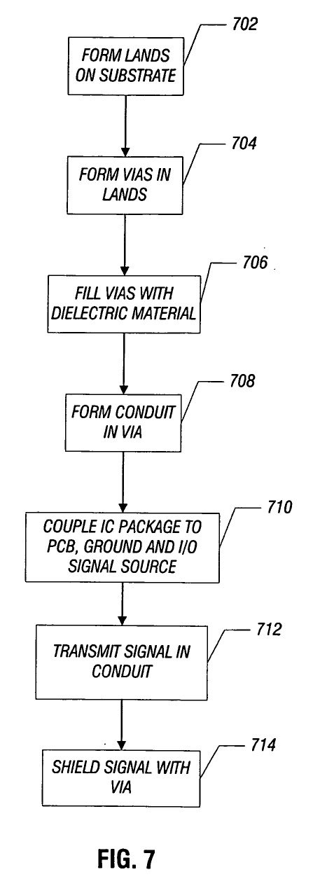

FIG. 7 is a flow diagram of a method of forming a PCB in accordance with another embodiment of the invention. In block 702, a plurality of lands are fabricated on a surface of a substrate such as a PCB. In block 704, a via is formed in each land. In one embodiment, the vias are formed by drilling; however, the scope of embodiments of the subject matter is not limited to drilling, and any suitable process for forming vias can be used, such as punching, microperforation, ablation, laser blasting, etching, and so forth. In one embodiment of the invention, the interior walls of the vias are plated or otherwise coated with an electrically conductive material, such as copper, after the vias are formed. In such an embodiment, the vias form PTH vias.

In 706, a material is applied over the surface (top and/or bottom) of the substrate, including the interior of some or all of the vias. The material may comprise a thermally expansive substance such as a dielectric material (e.g., SiO2). The thermally expansive substance can be applied to the upper and/or lower surface of the substrate. The thermally expansive substance, after heating, may substantially fill the via.

In block 708, a conduit or conduits are formed in each land. In one embodiment, the conduits may include signal vias that are located in PTH vias. The signal vias may be formed by drilling, punching, microperforation, ablation, laser blasting, etching, or by other methods known to those of ordinary skill in the art. In one embodiment of the invention, the interior walls of the signal vias may be filled, plated or otherwise coated with an electrically conductive material, such as copper, after the signal vias are formed.

In block 710, an IC package having a plurality of contacts (e.g. solder balls in a ball grid array configuration) is aligned with respect to the signal vias on the substrate surface. A heating operation (e.g. a solder reflow operation) may then be carried out in which the balls and signal vias are heated until they electrically and physically join. In one embodiment of the invention, each signal via is coupled to a land at each end of the signal via. The lands may facilitate coupling between the balls and signal vias. Lands may also be formed for shield vias such as those vias coupled to Vss. The signal via lands may be electrically isolated from other via lands using, for example, etching techniques known to those of ordinary skill in the art. Furthermore, the shield vias may be connected to a ground source and the signal vias may be connected to, for example, I/O signal sources.

In block 712, I/O signals may be transmitted via the signal vias. As indicated in the block 714, the outer via may shield signals transmitted through the signal vias from, for example, EMI and cross-talk noise. In alternative embodiments of the invention, one or more inner vias may be connected to power sources.

The operations described above with respect to FIGS. 6 and 7 can be performed in a different order from those described herein. For example, in FIG. 7 the lands could be formed after the shield vias are formed. Furthermore, the PCB discussed in block 702 of FIG. 7 can be any type of substrate on which electrical components can be mounted, such as a material formed of polyimide, a suitable organic material, silicon, glass, quartz, ceramic, and the like. Further still, an electrical component in the package mounted to the PCB in block 710 can be of any type, such as an IC or other semiconductor device; a passive element such as an inductor, capacitor, or resistor; or any other kind of electrical or electronic device. If the electrical component in the package is an IC, it can be of any type, such as a microprocessor or microcontroller, memory circuit, application specific integrated circuit (ASIC), digital signal processor (DSP), a radio frequency circuit, an amplifier, a power converter, a filter, a clocking circuit, and the like.

In FIGS. 1, 2, 3, 4, and 5, the substrate showed therein has been referred to as a semiconductor package substrate. However, in alternative embodiments of the invention, the via structure discussed herein may be utilized, for example, in PCB's, also known as printed wire boards, and semiconductors devices or dies.

While the present invention has been described with respect to a limited number of embodiments, those skilled in the art will appreciate numerous modifications and variations there from. It is intended that the appended claims cover all such modifications and variations that falls within the true spirit and scope of this present invention.

What is claimed is:

1. An apparatus comprising:
a substrate having a first portion and a second portion;
a first opening to couple the first portion to the second portion; and
a first conduit having at least a portion thereof located within the first opening to communicate a first signal along the first conduit.

2. The apparatus of claim 1, wherein the first portion is coupled to ground.

3. The apparatus of claim 1, wherein the apparatus comprises a package substrate.

4. The apparatus of claim 1, wherein the first opening comprises a via.

5. The apparatus of claim 4, wherein the first portion is a first layer of the substrate and the second portion is a second layer of the substrate.

6. The apparatus of claim 1, further comprising a second conduit having at least a portion thereof located within the first opening to communicate a second signal along the second conduit.

7. The apparatus of claim 6, wherein the first signal and the second signal comprise a differential signal pair.

8. The apparatus of claim 7, wherein the first opening is to shield the differential signal pair.

9. The apparatus of claim 1, further comprising a second conduit having at least a portion thereof located within the first conduit to communicate a second signal along the second conduit.

10. A method comprising:
forming a first opening, in a substrate having a first portion and a second portion, to couple the first portion to the second portion; and
locating at least a portion of a first conduit within the first opening to communicate a first signal along the first conduit.

11. The method of claim 10, further comprising locating at least a portion of a second conduit within the first opening to communicate a second signal along the second conduit.

12. The method of claim 10, further comprising coupling the first opening to a metal layer.

13. The method of claim 10, further comprising:
coating at least a portion of an inner wall of the first opening with a metal; and
coating at least a portion of the metal coating with a dielectric material.

14. The method of claim 10, further comprising coupling the first opening to ground.

15. The method of claim 10, further comprising at least partially filling the first conduit with a metal.

16. The method of claim 10, further comprising locating at least a portion of a second conduit within the first conduit to communicate a second signal along the second conduit.

17. A system comprising:
a semiconductor device;
a motherboard; and
a package substrate to couple the semiconductor device to the motherboard, wherein the package substrate has a first portion, a second portion, a first opening to couple the first portion to the second portion, and a first conduit having at least a portion thereof located within the first opening to communicate a first signal along the first conduit.

18. The system of claim 17, further comprising a second conduit having at least a portion thereof located within the first opening to communicate a second signal along the second conduit.

19. The system of claim 18, wherein the first opening is to shield the first signal and the second signal.

20. The system of claim 17, further comprising a second conduit having at least a portion thereof located within the first conduit to communicate a second signal along the second conduit.
